(19) United States
(12) Patent Application Publication
(10) Pub. No.: US 2015/0000959 A1
(43) Pub. Date: Jan. 1, 2015

(54) MULTILAYER PRINTED CIRCUIT BOARD HAVING ANISOTROPY CONDICTIVE FILM AND METHOD FOR MANUFACTURING SAME

(71) Applicant: Zhen Ding Technology Co., Ltd., Taoyuan (TW)

(72) Inventor: WEI-SHUO SU, Taoyuan (TW)

(21) Appl. No.: 14/317,137

(22) Filed: Jun. 27, 2014

(30) Foreign Application Priority Data
Jun. 27, 2013 (CN) 201310260436X

(51) Int. Cl. H05K 1/14; H05K 3/36; H05K 1/11

(52) U.S. Cl. CPC H05K 1/144; H05K 1/113; H05K 3/36
USPC 174/251; 29/830

(57) ABSTRACT

A multilayer printed circuit board (PCB) includes a first and second PCB component, and an anisotropic conductive film (ACF). The first PCB component includes a first base isolative layer, additional circuited layers and isolative layers alternately stacked on the first base isolative layer, and a number of conductive posts protruding out of the first base isolative layer away from the additional circuited layers and the isolative layers. The second PCB component includes a second base isolative layer, additional circuited layers and isolative layers alternately stacked on the second base isolative layer, and a number of pads are formed on the second base isolative layer opposite to the additional layers and the isolative layers. Each conductive post is aligned with one of the pads. The ACF is sandwiched between and bonds the first base isolative layer and the second base isolative layer together.

### FIELD

The present disclosure relates to printed circuit boards (PCBs), and particularly, to a multilayer PCB having an anisotropy conductive film (ACF) and a method for manufacturing the multilayer PCB.

### BACKGROUND

With developments of electronic devices, small-sized and high-speed PCBs are in demand. As such, multilayer PCBs of more complex and denser wiring structures are being developed. The Multilayer PCB often includes a great number of circuited layers built on a relatively thick core.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is a cross-sectional view of a first PCB component, according to an embodiment.

FIG. 2 is a cross-sectional view of a second PCB component, according to the embodiment.

FIG. 3 is a cross-sectional view of the first PCB component of FIG. 1 and the second PCB component of FIG. 2 bonded by an anisotropic conductive adhesive, according to the embodiment.

FIG. 4 is a cross-sectional view of a multilayer PCB, according to the embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.”

Embodiments of the present disclosure will be described with reference to the drawings.

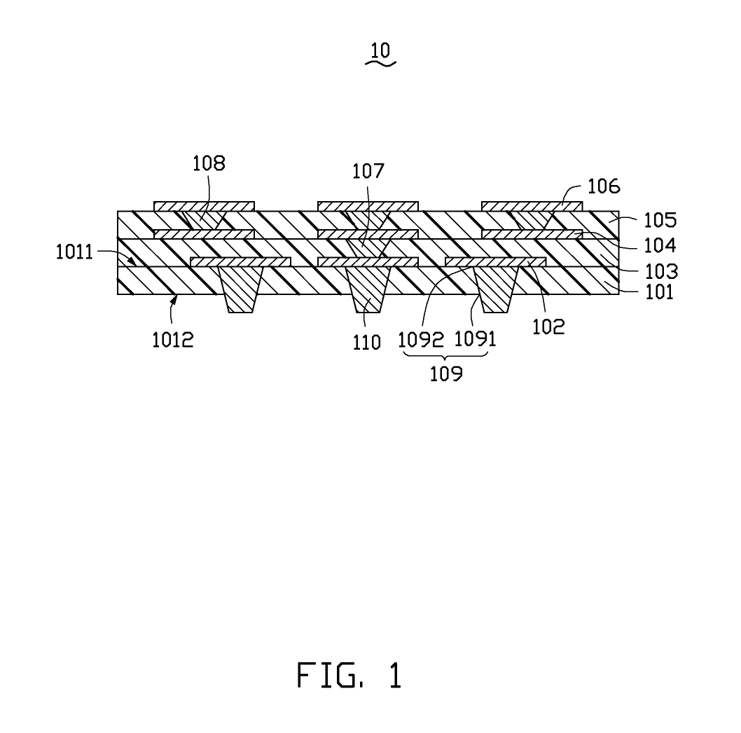

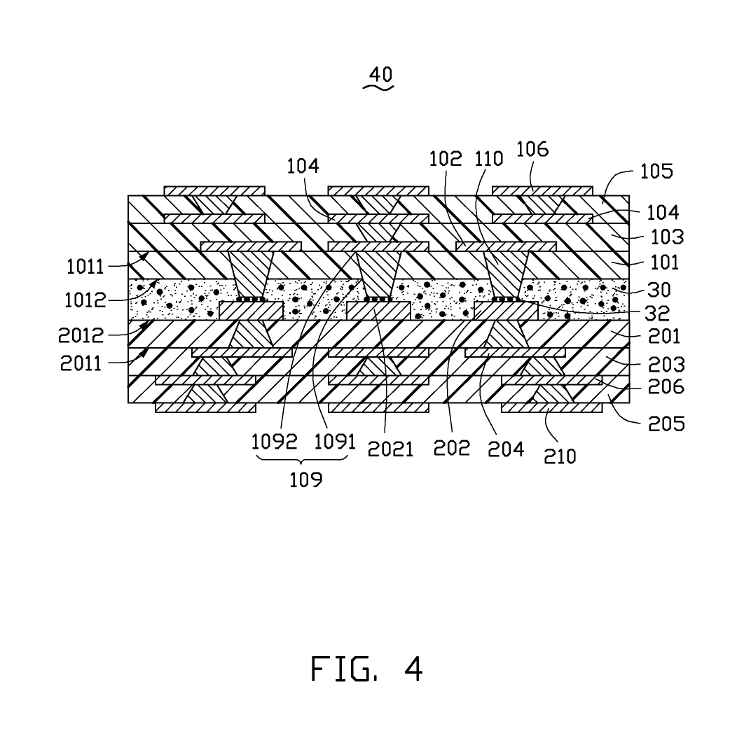

FIGS. 1-4 illustrate a method for manufacturing a multilayer PCB 40 (see FIG. 4). The method includes the following steps.

In the first step, as shown in FIG. 1, a first PCB component 10 is provided.

The first PCB component 10 includes a first base isolative layer 101. The first PCB component also includes a first base circuited layer 102, a first isolative layer 103, a first circuited layer 104, a second isolative layer 105, and a second circuited layer 106, stacked in order on the first base isolative layer 101.

The first PCB component 10 also includes a number of first vias 107 and second vias 108. The first vias 107 extend through the first isolative layer 103 and connect the first base circuited layer 102 with the first circuited layer 104 in a desired manner. The second vias 108 extend through the second isolative layer 105 and connect the first circuited layer 104 with the second circuited layer 106.

In detail, the first base isolative layer 101 includes a first surface 1011 and a second surface 1012 opposite to the first surface 1011. The first base circuited layer 102 is stacked on the first surface 1011. The first PCB component 10 defines a number of through holes 109 through the first base isolative layer 101. Each through hole 109 forms a first opening 1091 at the second surface 1012 and a second opening 1092 at the first surface 1012. The through holes 109 taper from the first opening 1091 towards the second opening 1092.

The first PCB component 10 also includes a number of conductive posts 110. Each conductive post 110 is inserted in one of the through holes 109 and protrudes out from the first opening 1091. Each conductive post 110 connects the first base circuited layer 102 and also tapers from an end that contacts the first base circuited layer 102 to an opposite end.

A configuration of the first PCB component 10 is not limited to this embodiment and can be changed depending on need, for example, the first PCB component 10 can have less or more than three circuited layers.

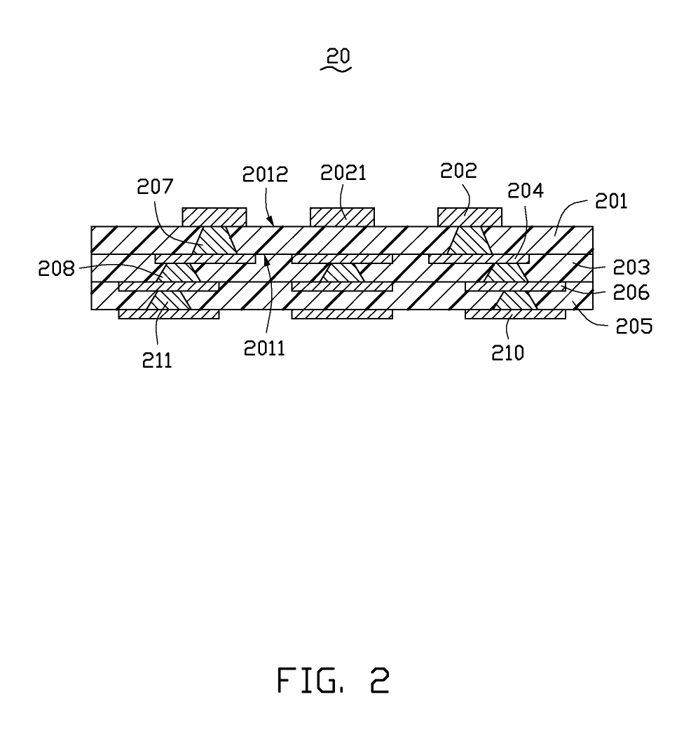

In a next step, as shown in FIG. 2, a second PCB component 20 is provided.

The second PCB component 20 includes a second base isolative layer 201. The second PCB component 20 also includes a second base circuited layer 204, a third isolative layer 203, a third circuited layer 206, a fourth isolative layer 205, and a fourth circuited layer 210, stacked in order on the second base isolative layer 201. The second PCB component 20 also includes a fifth circuited layer 202 stacked on the second base isolative layer 201, opposite to the second base circuited layer 204. The second PCB component 20 also includes a number of third vias 211, fourth vias 208, and fifth vias 207. The third vias 211 extend through the fourth isolative layer 205 and connect the fourth circuited layer 210 with the third circuited layer 206. The fourth vias 208 extend through the third isolative layer 203 and connect the third circuited layer 206 with the second base circuited layer 204. The fifth vias 207 extend through the second base isolative layer 201 and connect the second base circuited layer 204 with the fifth circuited layer 202.

The second base isolative layer 201 includes a third surface 2011 and a fourth surface 2012 opposite to the first surface 2011. The fourth surface 2012 is substantially identical to the second surface 1012 in shape and size. The second base circuited layer 204 is stacked on the third surface 2011 and the fifth circuited layer 202 is stacked on the fourth surface 2012. The fifth circuited layer 202 forms a number of pads 2021 corresponding to the conductive posts 110 in number and position.

A configuration of the second PCB component 20 is not limited to this embodiment and can be changed depending on need, for example, the second PCB component 20 can have less or more than four circuited layers.

The first PCB component 10 and the second PCB component 20 can be made by a layer buildup method. For example, the first PCB component 10 is made by building up, in order, the first base circuited layer 102, the first isolative layer 103, the first circuited layer 104, the second isolative layer 105, and the second circuited layer 106 on the first surface 1011. The second PCB component 20 can be made by building up, in order, the second base circuited layer 204, the third isolative layer 203, the third circuited layer 206, the fourth isolative layer 205, and the fourth circuited layer 210 on the third surface 2011.

The first vias 107, the second vias 108, the conductive posts 110, the third vias 211, the fourth vias 208, and the fifth vias 207 can be made by electroplating of copper, tin, or silver.

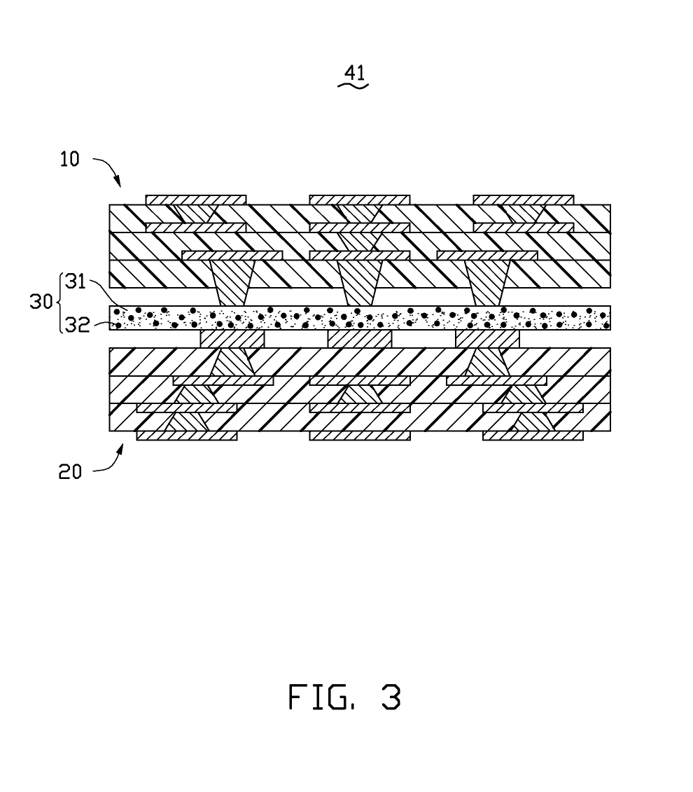

In the third step, as shown in FIG. 3, an ACF 30 is provided and is sandwiched between the first PCB component 10 and the second PCB component 20. The ACF 30 is substantially identical with the second surface 1012 and the fourth surface 2012 in shape and size. The ACF 30 includes an adhesive layer 31 and a number of conductive particles 32 dispersed in the adhesive layer 31. The conductive posts 110 and the pads 2021 contact the ACF 30, each conductive post 110 is aligned with one of the pads 2021.

In the fourth step, as shown in FIG. 4, the first PCB component 10 and the second PCB component 20 are thermally pressed towards each other until the ACF 30 is deformed and contacts with the second surface 1012 and the fourth surface 2012 to form the multilayer PCB 40. That is, the second surface 1012 and the fourth surface 2012 are bonded together via the adhesive layer 31, and the conductive posts 110 are electrically connected with the pads 2021 by the conductive particles 32 located therebetween. As such, the first PCB component 10 and the second PCB component 20 cooperatively form a complete circuit with desired functions.

The multilayer PCB 40 can be a flexible PCB, a rigid PCB, or a rigid-flex PCB.

A relatively thick core used in conventional multilayer PCBs may be omitted in the multilayer PCB 40, as such; a thickness of the multilayer PCB 40 is reduced. In addition, in the multilayer PCB 40, the first PCB component 10 and the second PCB component 20 are built up in reverse directions, as such, balancing the warping of the first PCB component 10 and the second PCB component 20 caused by thermal processing, such as thermal pressing.

It will be understood that the above particular embodiments are shown and described by way of illustration only. The principles and the features of the present disclosure may be employed in various and numerous embodiments thereof without departing from the scope of the disclosure. The above-described embodiments illustrate the possible scope of the disclosure but do not restrict the scope of the disclosure.

What is claimed is:

1. A multilayer printed circuit board (PCB) comprising:
a first PCB component comprising a first base isolative layer, a first base circuited layer built on the first base isolative layer, and a plurality of conductive posts, the first base isolative layer defining a plurality of through holes therethrough, each conductive post being inserted through one of the through holes, the conductive posts connecting the first circuited layer and protruding out of the first base isolative layer;
a second PCB component comprising a second base isolative layer, a second base circuited layer built on the first base isolative layer, a plurality of pads forms on the second base isolative layer opposite to the second base circuited layer, and a plurality of vias extending through the second base isolative layer and connecting the pads with the second base circuited layer, each conductive post being aligned with one of the pads; and
an anisotropic conductive film sandwiched between the first base isolative layer and the second base isolative layer and bonding the first base isolative layer and the second base isolative layer together;
wherein each conductive post tapers from an end that contacts the first base circuited layer to another end.

2. The multilayer PCB of claim 1, wherein the first PCB component comprises additional isolative layers and circuited layers alternately stacked on the first base circuited layer.

3. The multilayer PCB of claim 2, wherein the first PCB component comprises additional vias for interconnecting each two adjacent additional circuited layers.

4. The multilayer PCB of claim 1, wherein second PCB component comprises additional isolative layers and circuited layers alternately stacked on the second base circuited layer.

5. The multilayer PCB of claim 4, wherein the second PCB component comprises additional vias for interconnecting each two adjacent additional circuited layers.

6. The multilayer PCB of claim 1, wherein the first base isolative layer comprises a first surface and a second surface opposite to the first surface, the first base circuited layer is stacked on the first surface, each through hole forms a first opening in the first surface and a second opening in the second surface, and the first opening is larger than the second opening.

7. The multilayer PCB of claim 6, wherein each through hole tapers from the first opening towards the second opening.

8. A method for manufacturing a multilayer PCB, comprising:
providing a first PCB component comprising a first base isolative layer, a first base circuited layer built on the first base isolative layer, and a plurality of conductive posts, the first base isolative layer defining a plurality of through holes therethrough, each conductive post being inserted through one of the through holes, the conductive posts connecting the first circuited layer and protruding out of the first base isolative layer;
providing a second PCB component comprising a second base isolative layer, a second base circuited layer built on the first base isolative layer, a plurality of pads formed on the second base isolative layer opposite to the second base circuited layer, and a plurality of vias extending through the second base isolative layer and connecting the pads with the second base circuited layer, each conductive post being aligned with one of the pads; and
providing an anisotropic conductive film sandwiched between and bonding the first base isolative layer and the second base isolative layer together.

9. A method for manufacturing a multilayer printed circuit board (PCB), comprising:
providing a first PCB component comprising a first base isolative layer, a first base circuited layer built on the first base isolative layer, and a plurality of conductive posts, the first base isolative layer defining a plurality of through holes therethrough, each conductive post being inserted through one of the through holes, the conductive posts connecting the first circuited layer and protruding out of the first base isolative layer;
providing a second PCB component comprising a second base isolative layer, a second base circuited layer built on the first base isolative layer, a plurality of pads formed on the second base isolative layer opposite to the second base circuited layer, and a plurality of vias extending through the second base isolative layer and connecting the pads with the second base circuited layer, each conductive post being aligned with one of the pads;
sandwiching an anisotropic conductive film between the first base isolative layer and the second base isolative layer, the anisotropic conductive film including an adhesive layer and conductive particles dispersed in the adhesive layer; and
thermally pressing the first PCB component and the second PCB component towards each other until the anisotropic conductive film is deformed and the conductive posts protruding out of the first base isolative layer become electrically connected to their respective aligned ones of the aligned pads of the second PCB component through some of the conductive particles, which are located between the conductive posts protruding out of the first base isolative layer and their respective aligned ones of the aligned pads of the second PCB component, and the first PCB component becomes bonded to the second PCB component by the adhesive layer of the anisotropic conductive film.
